(19) United States
(12) Patent Application Publication
(10) Pub. No.: US 2024/0224548 A1
(43) Pub. Date: Jul. 4, 2024

(54) EFFICIENT INDOOR PHOTOVOLTAIC CELL BASED ON TWO-DIMENSIONAL MXENE NANOSHEETS AND MANUFACTURING METHOD THEREOF

(71) Applicant: KOREA UNIVERSITY RESEARCH AND BUSINESS FOUNDATION, Seoul (KR)

(72) Inventors: Jae Won SHIM, Seoul (KR); Tae Hyuk KIM, Seoul (KR); Muhammad Ahsan SAEED, Seoul (KR); Asif SHAHZAD, Uppsala (SE)

(21) Appl. No.: 18/400,789

(22) Filed: Dec. 29, 2023

(30) Foreign Application Priority Data
Nov. 15, 2022 (KR) 10-2022-0152416

(51) Int. Cl. H10K 30/30; H10K 30/50; H10K 85/10; H10K 85/20; H10K 85/60

(52) U.S. Cl. CPC H10K 30/30; H10K 30/50; H10K 85/113; H10K 85/151; H10K 85/215; H10K 85/626; H10K 85/657

(57) ABSTRACT

Disclosed are an efficient indoor photovoltaic cell using two-dimensional transition metal carbides, MXene nanosheets and a manufacturing method thereof. According to the present invention, provided is an indoor photovoltaic cell including: a transparent lower electrode through which indoor light passes, an organic semiconductor layer in which a donor and a receptor generating an exciton by the indoor light and separating the exciton into a positive charge and a negative charge, and MXene having a predetermined concentration are mixed, and an upper electrode absorbing the negative charge.

### CROSS-REFERENCE TO RELATED APPLICATION

This application claims under 35 U.S.C. § 119(a) the benefit of Korean Patent Application No. 10-2022-0152416 filed on Nov. 15, 2022, the entire contents of which are incorporated herein by reference.

### BACKGROUND

### (a) Technical Field

The present invention relates to an efficient indoor photovoltaic cell based on two-dimensional MXene nanosheets and a manufacturing method thereof.

### (b) Background Art

The performance of an indoor photovoltaic cell is greatly affected by the surface form of an organic semiconductor layer corresponding to a photoactive layer and low free charge generation characteristics.

The use of existing additive materials in the organic semiconductor layer is faced with the problem of manipulating aggregation in the organic semiconductor layer for efficient charge separation and transportation.

In addition, effective free charge generation under light irradiation inhibits recombination and is very important for improving the performance of the indoor photovoltaic cell.

1-chloronaphalene (CN), an additive used in the existing organic semiconductor layer, is an additive widely used in a non-fleurene (NFA) based organic semiconductor, and is advantageous for vertical phase separation, but has limited problems with low miscibility, small exciton dissociation efficiency, and control over the shape of an NFA mixture in a solvent.

### SUMMARY OF THE DISCLOSURE

In order to solve the problem in the related art, the present invention provides an efficient indoor photovoltaic cell using 2-dimensional MXene nanosheets and a manufacturing method thereof, which can reduce a surface defect and a trap region.

In order to achieve the object, according to an embodiment of the present invention, provided is an indoor photovoltaic cell including: a transparent lower electrode through which indoor light passes; an organic semiconductor layer in which a donor and a receptor generating an exciton by the indoor light and separating the exciton into a positive charge and a negative charge, and MXene having a predetermined concentration are mixed; and an upper electrode absorbing the negative charge.

The MXene may be a laminated body of unit MXene represented by Formula1 below:

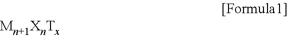

wherein, M is a transition metal selected from titanium (Ti), zirconium (Zr), hafnium (Hf), vanadium (V), chromium (Cr), manganese (Mn), scandium (Sc), molybdenum (Mo), niobium (Nb), tantalum (Ta), or a combination thereof,
X is carbon (C), nitrogen (N), or a combination thereof,
n is an integer of 1 to 3, and
Tx is a terminal of MXene unit, which is oxygen (O), hydroxide (OH), epoxide, carbon water 1-5 alkoxide, fluoride (F), chloride (Cl), bromide (Br), iodide (I), or a combination thereof.

The donor may be one of PM6 (PBDB-T-2F) and PM7 (PBDB-T-2Cl), and the receptor may be one of Y6 (BTP-4F) and PC71BM.

The MXene may have the concentration of 0.02 to 0.08 volume percent, and more preferably the MXene have the concentration of 0.04 to 0.06 volume percent.

The indoor photovoltaic cell may further include: a hole transport layer disposed between the transparent lower electrode and the organic semiconductor layer, and transporting the positive charge generated in the organic semiconductor layer; and an electron transport layer disposed between the upper electrode and the organic semiconductor layer, and transporting the negative charge generated in the organic semiconductor layer.

According to another embodiment of the present invention, provided is a manufacturing method of an indoor photovoltaic cell, including: forming a transparent lower electrode through which indoor light passes on a substrate; forming an organic semiconductor layer, in which a donor and a receptor, and MXene having a predetermined concentration are mixed to generate an exciton by the indoor light, and separate the exciton into a positive charge and a negative charge, on the transparent lower electrode; and forming an upper electrode absorbing the negative charge on the organic semiconductor layer.

According to the present invention, there is an advantage in that a uniform surface form and a reduced particle boundary are provided by adding 2-dimensional MXene to an organic semiconductor layer of an indoor photovoltaic cell, thereby maximizing indoor photovoltaic cell performance.

In addition, according to the present invention, there is an advantage in that photo conductivity and optical absorption can be enhanced through MXene nanosheets.

### BRIEF DESCRIPTION OF THE DRAWINGS

FIG. 1A is a diagram illustrating a synthetic schematic view of exfoliated 2-dimensional MXene (dl-Ti₃C₂Tₓ) according to the embodiment.

FIG. 1B is a diagram illustrating a photo acquired by observing multi-layer Ti₃C₂Tₓ by using a SEM microscope according to the embodiment.

FIG. 1C is a photo illustrating exfoliated Ti₃C₂Tₓ.

FIG. 1D is a diagram illustrating an energy-dispersive X-ray spectroscopy (EDS) element analysis result.

FIG. 1E is a diagram illustrating a transmission electron microscope (TEM) image of dl-Ti₃C₂Tₓ.

FIG. 2A is a diagram illustrating an indoor photovoltaic cell structure and various light source spectrums according to the embodiment.

FIG. 2B illustrates absorbance of a donor (PM6), a receptor (Y6), and an active layer mixture (PM6:Y6).

FIG. 2C is a diagram illustrating a chemical structure and energy levels of PM6 and Y6.

FIG. 3A is a diagram illustrating a 3D atomic force microscope (AFM) image according to various concentrations of MXene added to an organic semiconductor layer.

FIG. 3B is a diagram illustrating a 2D AFM particle number image.

FIG. 4A is a diagram illustrating a normalized absorption profile of the organic semiconductor layer.

FIG. 4B is a diagram illustrating a J-V curve of the indoor photovoltaic cell according to a 1-sun (AM1.5G) lighting.

FIG. 4C is a diagram illustrating an external quantum efficiency (EQE) spectrum of the indoor photovoltaic cell.

FIGS. 4D to 4F are diagrams illustrating J-V curves of the indoor photovoltaic cell according to LED 1000-lx, FL 1000-lx, and HL 1000-lx, respectively.

FIG. 4G is a diagram illustrating dependency of V_{OC} for a light intensity of the indoor photovoltaic cell.

FIG. 4H is a diagram illustrating dependency of J_{SC} for the light intensity of the indoor photovoltaic cell.

FIG. 4I is a diagram illustrating Jₚₕ-V_{eff} characteristics of a photovoltaic cell under an LED 1000-lx lighting.

### DETAILED DESCRIPTION

The present invention may make various modifications and has various embodiments, so specific embodiments will be illustrated in the drawings and described in detail in the detailed description. However, this is not to limit the present invention to specific embodiments, and it should be understood that the present invention covers all the modifications, equivalents and replacements included within the idea and technical scope of the present invention.

The terms used in the present specification are used only to describe specific embodiments, and are not intended to limit the present invention. A singular form includes a plural form unless the context clearly dictates otherwise. In this specification, it should be understood that the term “include” or “have” is intended to designate the presence of a feature, a number, a step, an operation, a component, a part or the combination thereof described in the specification, but not to preclude the possibility of the presence or addition of one or more other features, numbers, steps, operations, components, parts, or combinations thereof.

In addition, the components of the embodiment described with reference to each drawing are not limitedly applied only to the corresponding embodiment, and may be implemented to be included in another embodiment within the scope of maintaining the technical idea of the present invention, and further, even if a separate explanation is omitted, it is natural that a plurality of embodiments may be re-implemented as one embodiment.

In addition, in the description with reference to the accompanying drawings, the same components are assigned the same or related reference numerals regardless of the reference numerals, and redundant descriptions thereof will be omitted. In describing the present invention, a detailed description of related known technologies will be omitted if it is determined that they unnecessarily may obscure the gist of the present invention.

An indoor photovoltaic cell is constituted by a transparent lower electrode, an organic semiconductor layer corresponding to a photoactive layer, and an upper electrode, and an operation principle is as follows:

(i) High-energy photon absorption (i.e., light absorption), (ii) exciton generation (electron-hole pair), (iii) exciton dispersion in a donor-receptor interface before collapsing into a base state, (iv) transmission of the exciton to each electrode, and (v) charge collection.

In the operation principle of the indoor photovoltaic cell, the positive charge and the negative charge generated by light move to both electrodes according to a work function of a charge transport layer.

The organic semiconductor layer absorbs light and generates the exciton, and the exciton derived by indoor light is first dispersed at a donor-receptor interface according to a difference in energy level of the corresponding layer, and then moves to each electrode, and is collected in the forms of a positive charge and a negative charge to generate electricity.

A minimum photon number under low illuminance such as an indoor light source is consequently strongly affected by a surface defect and trap degrading indoor photovoltaic cell performance.

In the embodiment, two-dimensional MXene is applied to the organic semiconductor layer as an additive in order to reduce a surface defect and a trap region for performance enhancement of a high-performance indoor photovoltaic cell.

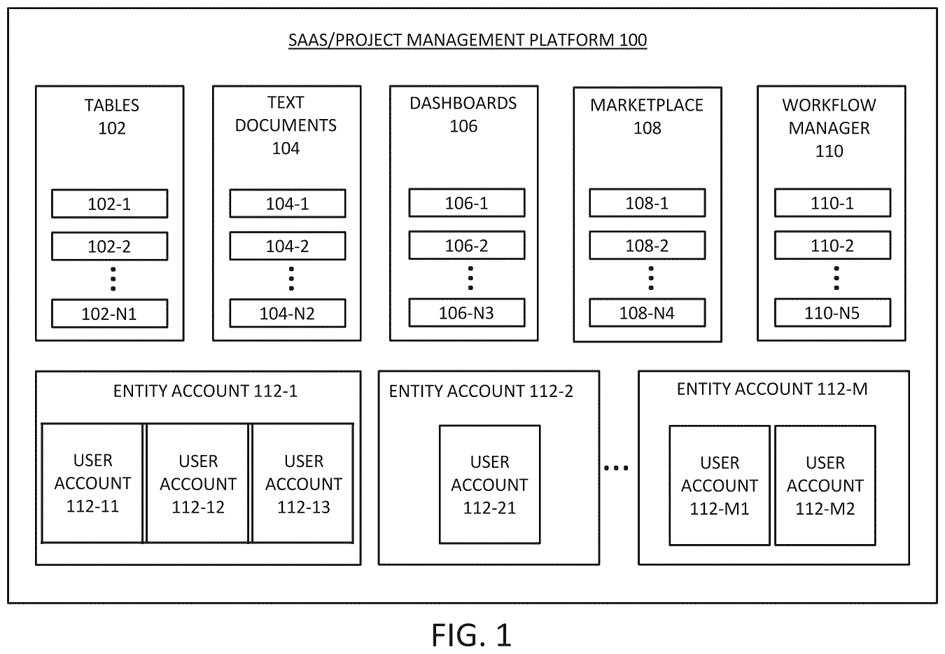

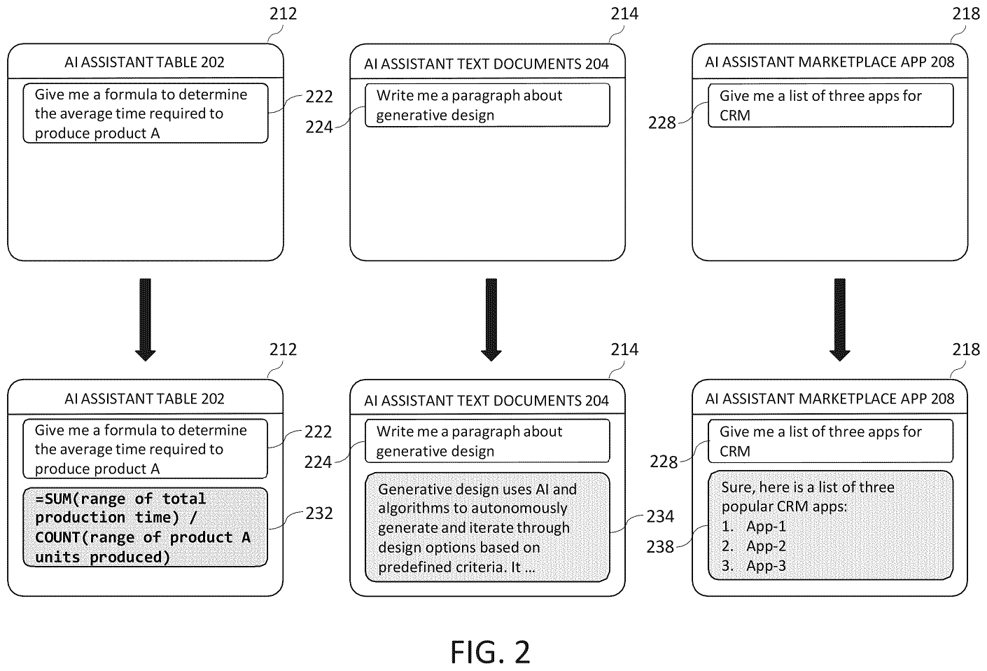

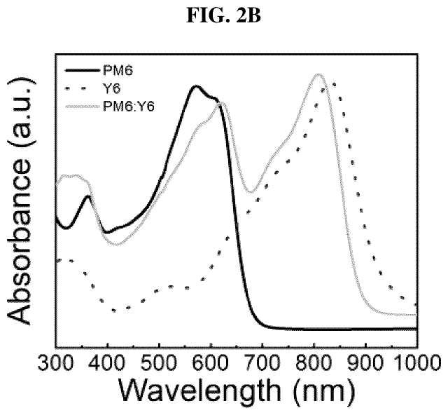

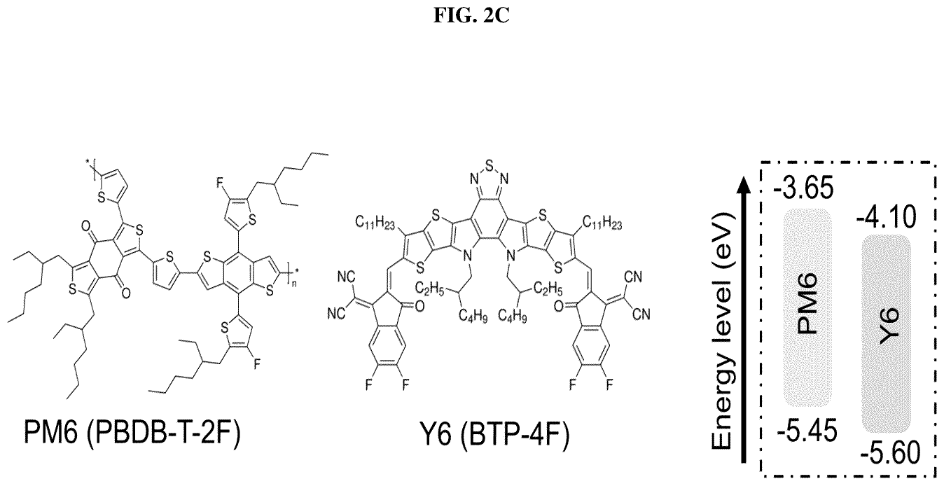

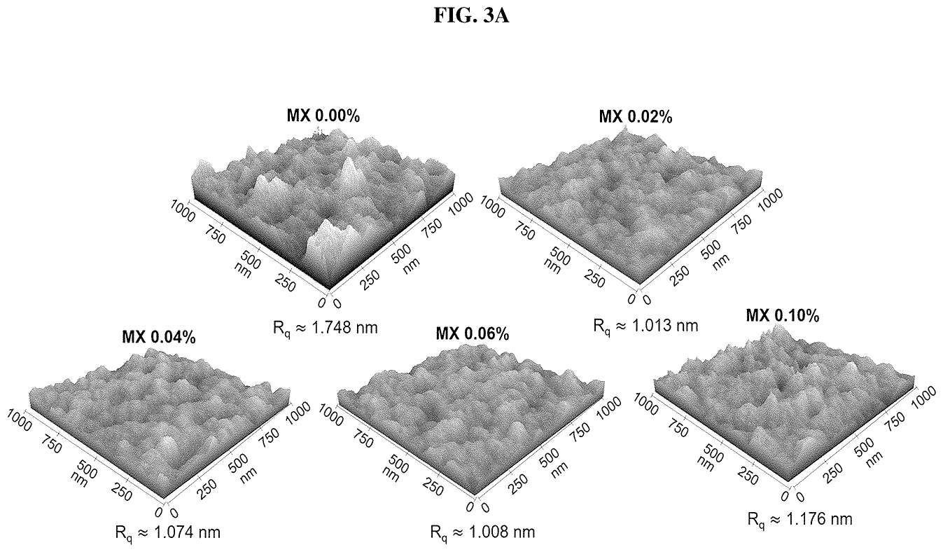

FIG. 1A is a diagram illustrating a synthetic schematic view of exfoliated two-dimensional MXene (dl-Ti₃C₂Tₓ) according to the embodiment.

Referring to FIG. 1A, titanium aluminum carbide (Ti₃ALC₂) is wet-chemically treated with hydrofluoric acid to synthesize titanium carbide MXene (Ti₃C₂Tₓ), and then Ti₃C₂Tₓ is exfoliated into nanosheets with a single- and/or few-layered thickness of dl-Ti₃C₂Tₓ through dimethyl sulfoxide and ultrasound treatment.

In FIG. 1A, two-dimensional MXene according to the embodiment is described as a titanium carbide MXene synthesized from titanium aluminum carbide, but it is not limited thereto, and MXene having Formula1 below may be mixed in an organic semiconductor layer constituted by a donor and a receptor:

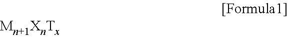

wherein, M is a transition metal selected from titanium (Ti), zirconium (Zr), hafnium (Hf), vanadium (V), chromium (Cr), manganese (Mn), scandium (Sc), molybdenum (Mo), niobium (Nb), tantalum (Ta), or a combination thereof,
X is carbon (C), nitrogen (N), or a combination thereof,
n is an integer of 1 to 3, and
Tx is a terminal of MXene unit, which is oxygen (O), hydroxide (OH), epoxide, carbon water 1-5 alkoxide, fluoride (F), chloride (Cl), bromide (Br), iodide (I), or a combination thereof.

Hereinafter, the description will focus on an indoor photovoltaic cell in which titanium carbide MXene having a predetermined concentration is mixed in the organic semiconductor layer.

FIG. 1B is a diagram illustrating a photo acquired by observing multi-layer Ti₃C₂Tₓ by using a scanning electrode microscope (SEM) according to the embodiment.

As in FIG. 1B, a nanosheet according to the embodiment shows a structure such as accordion of Ti₃C₂.

FIG. 1C is a photo illustrating exfoliated Ti₃C₂Tₓ.

Referring to FIG. 1C, since a nanosheet exfoliated into few-layers is stacked with increased surface roughness, and the size of exfoliated layered MXene nanosheets is not uniform, MXene should be dissolved in an organic solvent, and then left for a predetermined time or more, so that a more micro type of nanosheet may be mixed in the organic semiconductor layer.

FIG. 1D is a diagram illustrating an energy-dispersive X-ray spectroscopy (EDS) element analysis result.

As in FIG. 1D, extraction of an Al layer and presence of another element in Ti₃C₂Tₓ nanosheet may be confirmed from a MAX phase.

FIG. 1E is a diagram illustrating a transmission electron microscope (TEM) image of dl-Ti₃C₂Tₓ.

FIG. 1E illustrates a sheet type structure of Ti₃C₂Tₓ having a side size of approximately 500 nm averaged with respect to multiple nanosheets.

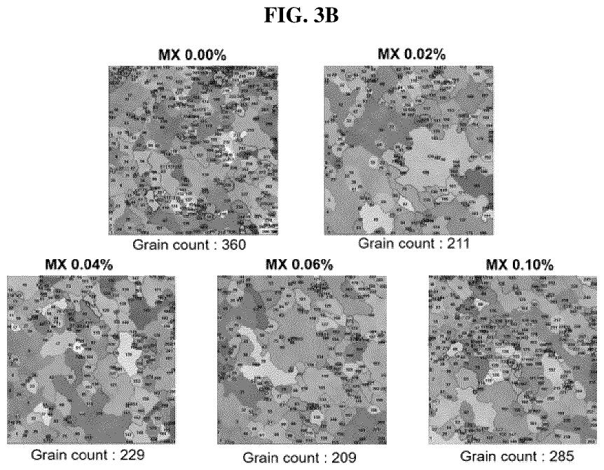

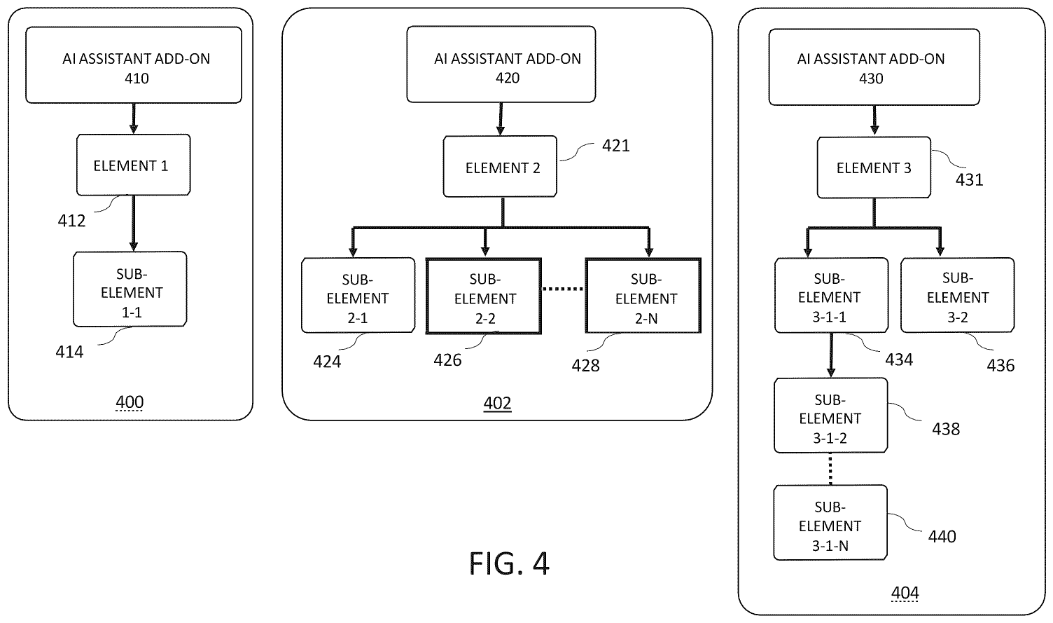

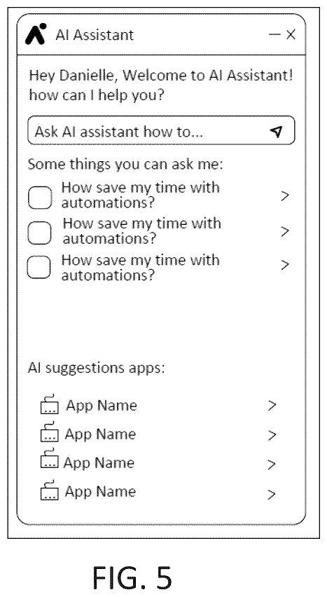

FIG. 2A is a diagram illustrating an indoor photovoltaic cell structure and various light source spectrums according to the embodiment.

Referring to FIG. 2A, the indoor photovoltaic cell according to the embodiment may include a transparent lower electrode through which indoor light passes, an organic semiconductor layer in which a donor and a receptor generating an exciton by the indoor light and separating the exciton into a positive charge and a negative charge, and MXene having a predetermined concentration are mixed, and an upper electrode absorbing the negative charge.

Here, ITO and Al may be used as the transparent lower electrode and the upper electrode, respectively.

The donor may be one of PM6 (PBDB-T-2F) and PM7 (PBDB-T-2Cl), and the receptor may be one of Y6 (BTP-4F) and PC71BM.

In addition, the indoor photovoltaic cell may further include a hole transport layer disposed between the transparent lower electrode and the organic semiconductor layer, and transporting the positive charge generated in the organic semiconductor layer, and an electron transport layer disposed between the upper electrode and the organic semiconductor layer, and transporting the negative charge generated in the organic semiconductor layer.

As illustrated in FIG. 2A, the hole transport layer according to the embodiment may be composed of 2PACz2PACz ([2-(9H-Carbazol-9-yl)ethyl]phosphonic Acid), and the electron transport layer may be composed of PDINO.

In addition, FIG. 2A illustrates an irradiation spectrum of a light source applied to the embodiment.

FIG. 2B illustrates absorbance of a donor (PM6), a receptor (Y6), and an active layer mixture (PM6:Y6).

FIG. 2C is a diagram illustrating a chemical structure and energy levels of PM6 and Y6.

Referring to FIG. 2C, appropriate energy level alignment between a material of the organic semiconductor layer and an interface guarantees high efficiency of the indoor photovoltaic cell.

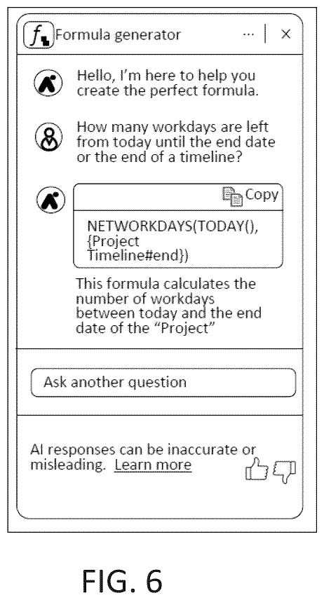

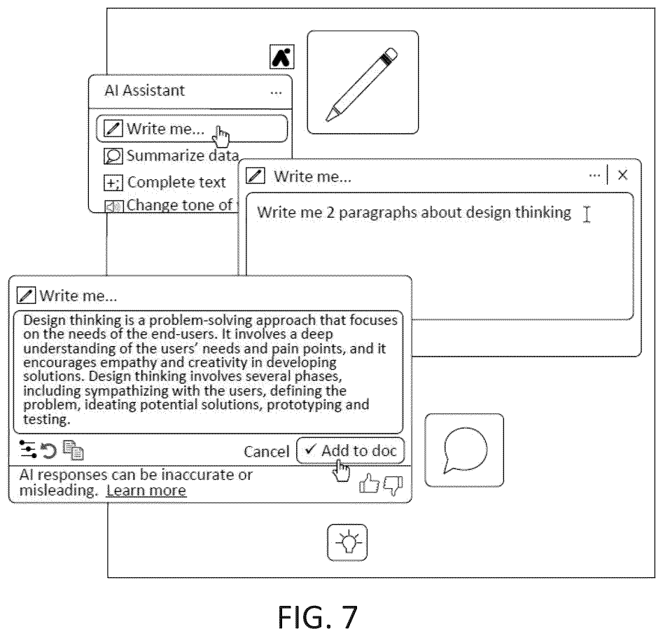

FIG. 3A is a diagram illustrating a 3D atomic force microscope (AFM) image according to various concentrations of MXene added to an organic semiconductor layer.

An organic semiconductor layer surface form including or not including MXene is evaluated through AFM analysis.

The PM6:Y6 mixture to which MXene is not added shows a mean square roughness (Ra) value of 1.748 nm.

According to the embodiment, the concentration of MXene mixed in the organic semiconductor layer may be 0.02 to 0.08 volume percent (%), more preferably 0.04 to 0.06 volume percent (%).

Referring to FIG. 3A, R_{q} of the mixture has been improved while MXene was introduced into the PM6:Y6 mixture, and R_{q} of 1,008 nm in MXene mixture of 0.06% shows excellent surface characteristics.

This means that an approach derived by an additive may minutely adjust molecular coagulation adjusted along with a uniform surface form.

FIG. 3B is a diagram illustrating a 2D AFM particle number image.

To quantify surface roughness, a watershed algorithm is used to calculate a particle boundary number of the organic semiconductor layer mixture.

FIG. 3B illustrates a grain size (1 μm²) of each organic semiconductor layer mixture.

The number of MXene particles of 0.00%, 0.02%, 0.04%, 0.06%, and 0.10% added to the organic semiconductor layer are 360, 211, 229, 209, and 285, respectively.

A large number of particles cause generation of more trap sites, and an increase of trap sites in the organic semiconductor layer exerts a significant influence on charge recombination, and consequently degrades the performance of indoor photovoltaic cell.

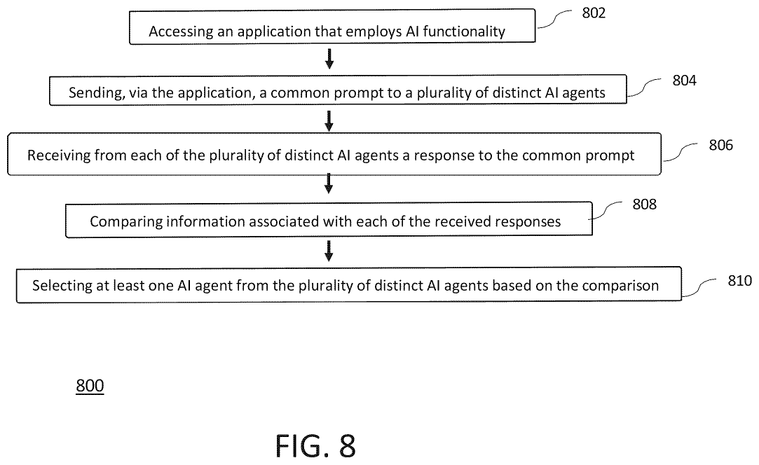

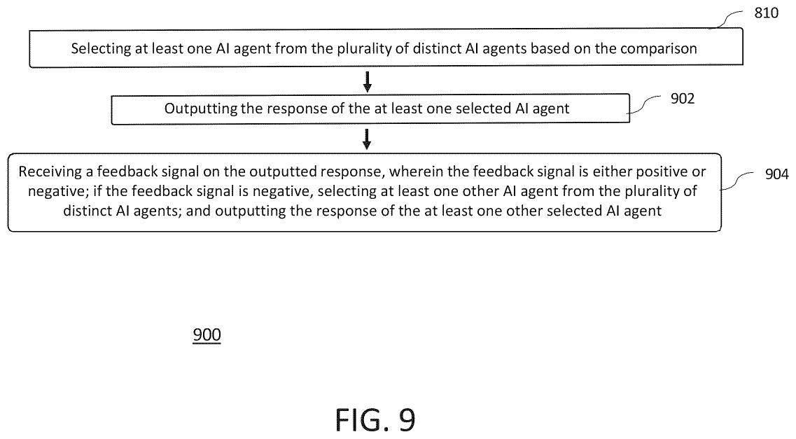

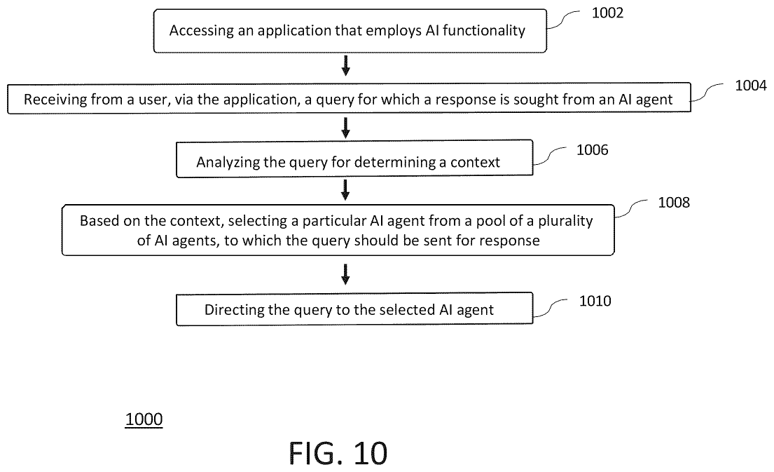

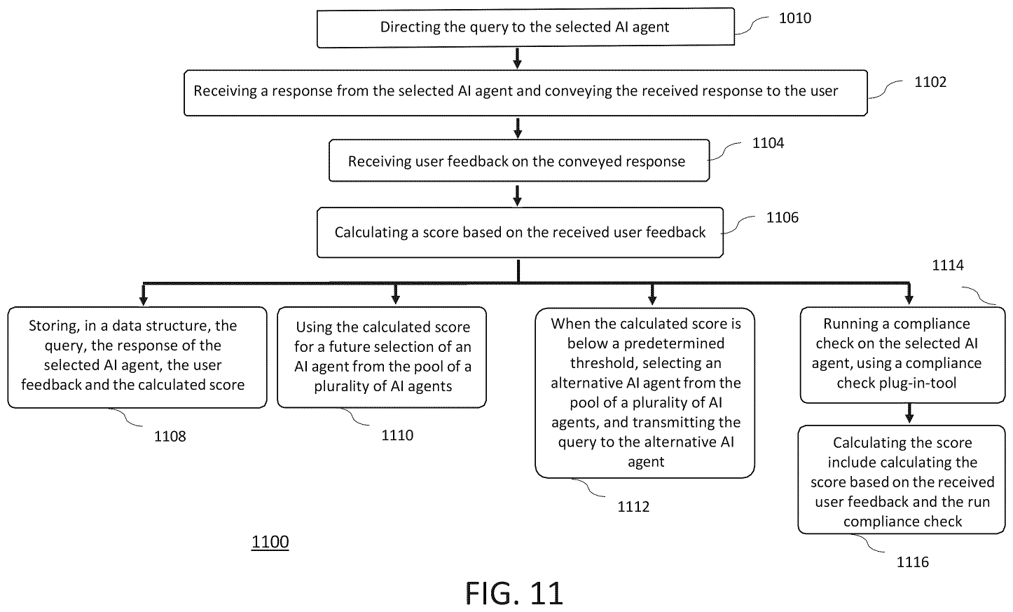

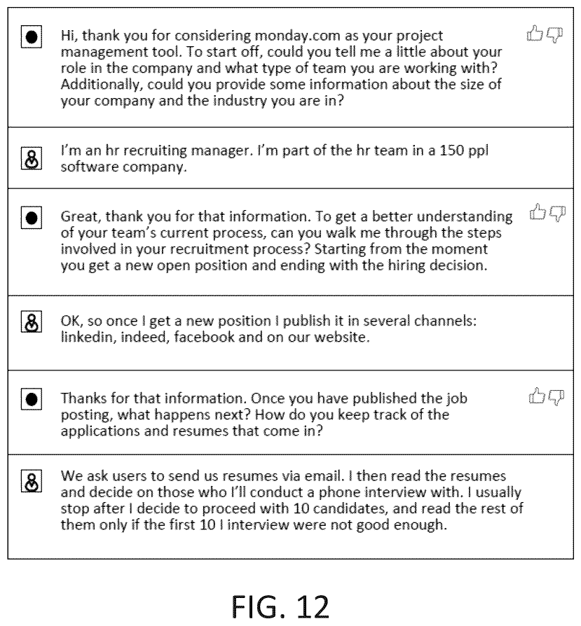

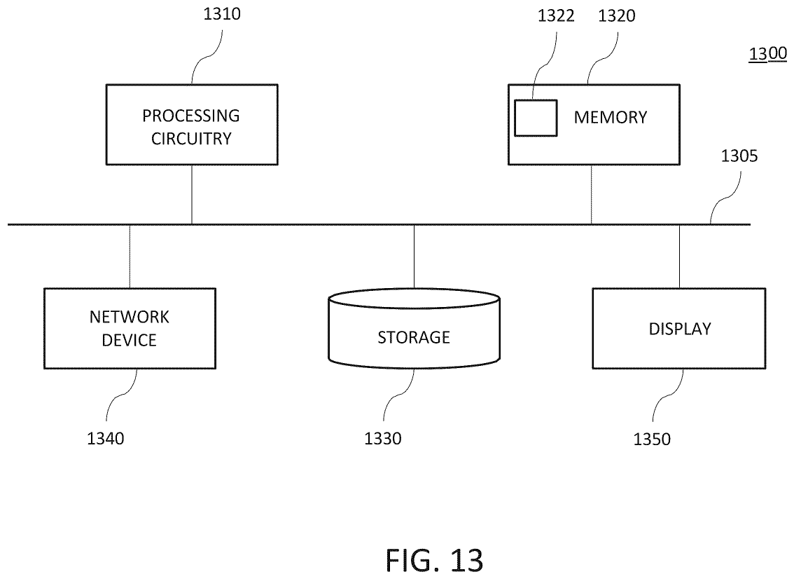

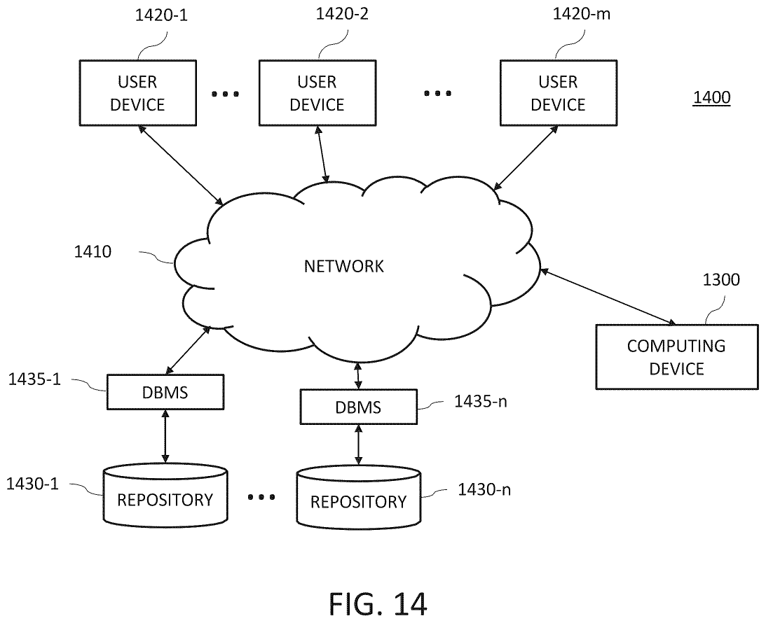

FIG. 4A is a diagram illustrating a normalized absorption profile of the organic semiconductor layer.

Referring to FIG. 4A, it may be confirmed that an absorption profile of the organic semiconductor layer is not widened by introduction of MXene.

Instead, when increasing the content of MXene in the PM6:Y6 mixture, an absorption strength of the mixture is gradually enhanced, and this may be caused by light scattering of an MXene flake.

FIG. 4B is a diagram illustrating a J-V curve of the indoor photovoltaic cell according to a 1-sun (AM1.5G) lighting.

Referring to FIG. 4B, an optimized indoor photovoltaic cell (an organic semiconductor layer including MXene of 0.06%) shows maximum means power conversion efficiency (PCE: 15.1±0.1%) of 16.0±0.1% enhanced by approximately 10% as compared with an indoor photovoltaic cell (MXene of 0.00%) without MXene.

FIG. 4C is a diagram illustrating an external quantum efficiency (EQE) spectrum of the indoor photovoltaic cell.

It may be confirmed that the indoor photovoltaic cell in which MXene is mixed in the organic semiconductor layer shows a relatively strong photon to electron reaction in a visible wavelength region as compared with the indoor photovoltaic cell (MXene of 0.00%) without MXene, so a J_{SC} value is increased as shown in an EQE spectrum.

FIGS. 4D to 4F are diagrams illustrating J-V curves of the indoor photovoltaic cell according to LED 1000-lx, FL 1000-lx, and HL 1000-lx, respectively.

In LED lighting (1000-lx, Irradiance=0.23 mW/cm²), indoor photovoltaic cells without MXene showed an average PCE of 27.5±0.1%, and a recording PCE (MX 0.06%) of 33.7±0.1% was proved under a condition in which MXene doped.

Similarly, in FL (1000-lx, Irradiance=0.27 mW/cm², FIG. 4E) and halogen (1000-lx, Irradiance=7.0 mW/cm², FIG. 4F), the photovoltaic cell using MXene shows the highest PCE of 32.8±0.2%, 5.5±0.1%, respectively.

Table 1 summarizes and shows the performance of the indoor photovoltaic cell under various light conditions.

TABLE 1

| Light | | V_{OC} | J_{SC} | FF | PCEₘₐₓ | |
|---|---|---|---|---|---|---|
| sources | Device type | [mV] | [μA/cm²] | [%] | (PCE_{avg})[%] | |
| 1-sun | MX 0.00% | 831 ± 3 | 26.0 ± 0.2 | 69.6 ± 0.5 | 15.2 | (15.1 ± 0.1) |
| 100 mW/cm² | MX 0.02% | 824 ± 4 | 25.7 ± 0.2 | 72.4 ± 0.3 | 15.5 | (15.3 ± 0.2) |
| | MX 0.04% | 828 ± 2 | 26.2 ± 0.3 | 73.1 ± 0.2 | 15.9 | (15.8 ± 0.1) |
| | MX 0.06% | 823 ± 3 | 26.8 ± 0.2 | 73.3 ± 0.2 | 16.1 | (16.0 ± 0.1) |
| | MX 0.10% | 824 ± 2 | 25.9 ± 0.4 | 72.3 ± 0.3 | 15.6 | (15.4 ± 0.2) |
| LED | MX 0.00% | 701 ± 2 | 132.9 ± 0.9 | 68.2 ± 0.8 | 27.5 | (27.4 ± 0.1) |
| 0.23 mW/cm² | MX 0.02% | 711 ± 2 | 139.5 ± 0.5 | 74.2 ± 0.4 | 32.0 | (31.9 ± 0.1) |
| (1000-lx) | MX 0.04% | 708 ± 3 | 141.9 ± 0.6 | 73.5 ± 0.4 | 32.3 | (32.1 ± 0.2) |
| | MX 0.06% | 707 ± 2 | 146.7 ± 0.1 | 74.9 ± 0.2 | 33.8 | (33.7 ± 0.1) |
| | MX 0.10% | 703 ± 2 | 141.6 ± 0.7 | 73.5 ± 1.0 | 31.7 | (31.6 ± 0.2) |
| FL | MX 0.00% | 705 ± 2 | 149.8 ± 1.4 | 68.9 ± 0.7 | 26.9 | (26.7 ± 0.2) |
| 0.27 mW/cm² | MX 0.02% | 710 ± 3 | 159.2 ± 0.7 | 74.5 ± 0.5 | 31 3 | (31.2 ± 0.1) |
| (1000-lx) | MX 0.04% | 707 ± 2 | 155.2 ± 1.1 | 74.7 ± 0.3 | 30.6 | (30.4 ± 0.2) |
| | MX 0.06% | 712 ± 3 | 166.1 ± 0.8 | 75.0 ± 0.3 | 33.0 | (32.8 ± 0.2) |
| | MX 0.10% | 705 ± 3 | 161.6 ± 0.5 | 72.7 ± 0.3 | 30.7 | (30.6 ± 0.1) |
| Halogen | MX 0.00% | 741 ± 4 | 649.6 ± 2.4 | 69.7 ± 1.0 | 4.8 | (4.7 ± 0.1) |
| 7.0 mW/cm² | MX 0.02% | 751 ± 3 | 656.7 ± 1.4 | 74.9 ± 1.1 | 5.3 | (5.2 ± 0.1) |
| (1000-lx) | MX 0.04% | 755 ± 2 | 675.5 ± 1.5 | 75.1 ± 0.4 | 5.5 | (5.3 ± 0.2) |
| | MX 0.06% | 752 ± 3 | 684.1 ± 2.1 | 75.3 ± 0.5 | 5.6 | (5.5 ± 0.1) |
| | MX 0.10% | 752 ± 4 | 668.5 ± 2.6 | 74.2 ± 0.3 | 5.4 | (5.3 ± 0.1) |

FIG. 4G is a diagram illustrating dependency of V_{OC} for a light intensity of the indoor photovoltaic cell.

Recombinant mechanics is determined by analyzing power law dependence of V_{OC} on I_{L}, and theoretically, n=1 represents the absence of trap support recombination, while n>1 represents the prevailing of the trap support recombination. A photovoltaic cell value doped with MXene has been found to be close to unity (n=1), which implies the inhibition of the trap support recombination because a trap site of the organic semiconductor layer is reduced.

FIG. 4H is a diagram illustrating dependency of J_{SC} for the light intensity of the indoor photovoltaic cell.

As illustrated in FIG. 4H, the dependence of J_{SC} on a light intensity I_{L} was investigated to quantify bimolecular recombination. Bimolecular recombination efficiency B may be represented as (B=1/s−1), and here, s=1 (B=0) represents the absence of the bimolecular recombination, and s<1 represents an increase of B representing the presence of the bimolecular recombination.

In the case of the indoor photovoltaic cell doped with MXene, a relatively low B value represents efficient extraction of a charge carrier generated in the active layer before re-bonding.

FIG. 4I is a diagram illustrating Jₚₕ-V_{eff} characteristics of a photovoltaic cell under an LED 1000-lx lighting.

The photocurrent density Jₚₕ is plotted on the effective voltage V_{eff}, and is represented by Jₚₕ=J_{SC}−Jₒ.

Here, J_{SC} and Jₒ are 1-sun (100 mW/cm²) and current density under dark conditions, respectively, and V_{eff}=Vₒ−Vₐ.

Here, Vₒ is voltage at Jₚₕ=0 and Va is source voltage.

The indoor photovoltaic cell doped with MXene becomes a saturation state at V_{eff}=0.126 (MX 0.06%) as compared with MXene of 0.00% (0.323) under the LED 1000 lx lighting.

This indicates that the charge trap density is greatly reduced by efficient charge transport and collection in the indoor photovoltaic cell doped with MXene, resulting in improved Fill Factor (FF) and PCE values.

The embodiment of the present invention is disclosed for the purpose of exemplification and it will be apparent to those skilled in the art that various modifications, changes, and additions can be made within the spirit and scope of the present invention, and these modifications, changes, and additions should be considered as falling within the scope of the following claims.

What is claimed is:

1. An indoor photovoltaic cell, comprising:
a transparent lower electrode through which indoor light passes;
an organic semiconductor layer in which a donor and a receptor generating an exciton by the indoor light and separating the exciton into a positive charge and a negative charge, and MXene having a predetermined concentration are mixed; and
an upper electrode absorbing the negative charge.

2. The indoor photovoltaic cell of claim 1, wherein the MXene is a laminated body of unit MXene represented by Formula1 below: 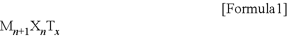
wherein, M is a transition metal selected from titanium (Ti), zirconium (Zr), hafnium (Hf), vanadium (V), chromium (Cr), manganese (Mn), scandium (Sc), molybdenum (Mo), niobium (Nb), tantalum (Ta), or a combination thereof,
X is carbon (C), nitrogen (N), or a combination thereof,
n is an integer of 1 to 3, and
Tx is a terminal of Maxine unit, which is oxygen (O), hydroxide (OH), epoxide, carbon water 1-5 alkoxide, fluoride (F), chloride (Cl), bromide (Br), iodide (I), or a combination thereof.

3. The indoor photovoltaic cell of claim 1, wherein the donor is one of PM6 (PBDB-T-2F) and PM7 (PBDB-T-2Cl), and the receptor is one of Y6 (BTP-4F) and PC71BM.

4. The indoor photovoltaic cell of claim 1, wherein the MXene has the concentration of 0.02 to 0.08 volume percent.

5. The indoor photovoltaic cell of claim 1, wherein the MXene has the concentration of 0.04 to 0.06 volume percent.

6. The indoor photovoltaic cell of claim 1, further comprising:
a hole transport layer disposed between the transparent lower electrode and the organic semiconductor layer, and transporting the positive charge generated in the organic semiconductor layer; and
an electron transport layer disposed between the upper electrode and the organic semiconductor layer, and transporting the negative charge generated in the organic semiconductor layer.

7. A manufacturing method of an indoor photovoltaic cell, comprising:
forming a transparent lower electrode through which indoor light passes on a substrate;
forming an organic semiconductor layer in which a donor and a receptor, and MXene having a predetermined concentration are mixed to generate an exciton by the indoor light, and separate the exciton into a positive charge and a negative charge, on the transparent lower electrode; and
forming an upper electrode absorbing the negative charge on the organic semiconductor layer.
